(19) United States
(12) Patent Application Publication
(10) Pub. No.: US 2008/0192428 A1
(43) Pub. Date: Aug. 14, 2008

(54) Thermal management system for computers

(76) Inventors: James E. Clayton, Raleigh, NC (US); Zakaryae Fathi, Raleigh, NC (US); James R. Gentry, Wake Forest, NC (US)

Correspondence Address: ROBERT J. LAUF, 998 W. OUTER DRIVE, OAK RIDGE, TN, 37830, US

(21) Appl. No.: 12/069,372

(22) Filed: Feb. 8, 2008

Related U.S. Application Data
(60) Provisional application No. 60/900,238, filed on Feb. 8, 2007.

(51) Int. Cl. G06F 1/20; H05K 7/20

(52) U.S. Cl. 361/687; 361/719; 361/694

(57) ABSTRACT

The invention involves systems to channel the air available for cooling inside the chassis of the computing device to force the air into selected channels in the memory bank (i.e., between the modules rather than around the modules or some other path of least resistance). This tunneled cooling (or collimated cooling) is made possible by using a set of baffles (or apertures) placed upstream of and between the cooling air supply and the memory bank area to force air to go only through the rectangular space available between adjacent modules in the memory bank of the high speed computing machines (super computers or blade servers in these cases). In some instances, it may be desirable to include both a blower fan, for forcing cool air through the baffles and through the heat exchanger(s) aligned with openings in the baffles, and a suction fan to draw or pull air as it exits the rear of the blade server chassis. The invention includes a high performance heat exchanger to be thermally coupled to the memory chips and either placed between adjacent modules (in the memory bank) or integrated within a cross sectional area of the module that is in the cooling air path; whereby, the heat from a given module is transferred laterally to a heat sink that, in turn, transfers the heat to the heat exchanger which in turn is placed in the path of cool air. However in this case, the cool air has no other alternative path but to pass through the high performance heat exchanger. The efficiency of heat exhaust is thereby maximized. Lateral heat conduction and removal is a preferred method for module cooling in order to minimize the total module height of vertically mounted Very Low Profile (VLP) memory modules. The invention is applicable to a wide range of modules; however, it is particularly suitable for a set of memory modules with unique packaging techniques that further enhance the heat exhaust.

### CROSS REFERENCE TO RELATED APPLICATION

This application claims the benefit of Provisional Patent Application No. 60/900,238 by the present inventors, filed on Feb. 8, 2007, the entire disclosure of which is incorporated herein by reference.

### BACKGROUND OF THE INVENTION

1. Field of the Invention

The invention pertains to systems and methods for managing heat generated in computers, and more particularly to systems and methods for managing coolant flow adjacent to various heat-generating components

2. Description of Related Art

Heat generation from semiconductor devices impedes functionality in high performance computing systems such as the blade server market sector. High-speed computers or Blade servers are space-constrained and their performance depends on the number of microprocessors and memory modules they contain. An increase in memory modules density is accompanied by significant heat generation, which leads to soft failures (Corrupt data stream). This is unacceptable to medical, financial & military centers. The current solutions are based on external air-cooling. First, memory modules and microprocessors are equipped with heat sinks to draw heat away from one (1) side of the chips. Second, forced air is used to carry the heat away from devices and out of the blade server enclosure. Practical air velocities and heat sink thickness have reached their limits. The heat sinks are so thick that they obstruct the air channels between adjacent modules.

For this reason, several solutions have been proposed to reduce the thickness of the memory modules. By doing so, the gap between adjacent modules is increased and air-cooling is rendered more effective. These solutions were described in James E. Clayton previously issued patents as well as pending one. The Issued Patents include U.S. Pat. No. 6,665,190; U.S. Pat. No. 6,232,659; U.S. Pat. No. 6,091,145; U.S. Pat. No. 6,049,975; U.S. Pat. No. 5,731,633; U.S. Pat. No. 5,751,553; U.S. Pat. No. 5,708,297; and U.S. Pat. No. 5,661,339, the entire disclosures of which are incorporated herein by reference.

These patents are based on the utilization of a core substrate and wrap-around flex circuit, which enables fragile Flip Chip or CSP packaged memory devices to be placed inside the substrate's core, rather than being exposed on the external surfaces of a traditional PCB. The resultant module is significantly thinner in cross-section and lower in mass.

The thinner cross-section enables more laminar airflow across the unobstructed external surfaces of the module and would allow adjacent modules to be spaced closer together with reduced mounting space on the motherboard. These attributes are extremely important for Blade Server applications

### OBJECTS AND ADVANTAGES

Objects of the present invention include: providing improved cooling to computer systems and components; providing more efficient flow of coolant adjacent to heat-generating components; providing more efficient use of space in compact computers, particularly blade servers; and, providing more efficient use of memory modules having integral heat exchange features. These and other objects and advantages of the present invention will become apparent from consideration of the following specification, read in conjunction with the drawings.

### BRIEF DESCRIPTION OF THE DRAWINGS

FIG. 1 illustrates schematically a thermal exhaust Flex-DIMM module with full rework capability.

FIG. 2 illustrates a cooling lid suitable for placement on a memory module.

FIG. 3 illustrates a multi-channel cooling lid for cooling both interior and exterior heat sinks.

FIG. 4 illustrates a high performance heat exchanger suitable for use in the present invention.

FIG. 5 illustrates a fully reworkable Flex DIMM with built-in heat exchanger. Dies are mounted on the Flex in an optimal way for heat transfer.

FIG. 6 illustrates alternate designs for full rank, full height versions of modules without flex folding.

FIG. 7 illustrates full rank low profile on indented metallic or plastic molded or PCB core with and without heat exchangers.

FIG. 8 illustrates a dual rank module implementation. Chips are mounted around a hollowed metallic frame with external heat sinks. The external heat sinks can be high performance heat exchangers.

FIG. 9 illustrates tunneled cooling at a memory bank level using a special baffle that blocks the air from going to any other path but the heat exchangers.

FIG. 10 illustrates tunneled cooling at a memory bank level using a special baffle that blocks the air from going to any other path but the heat exchangers.

### DETAILED DESCRIPTION OF THE INVENTION

Furthermore, as described in the Provisional Patent Application No. 60/780,440 by the present inventors, the entire disclosure of which is incorporated herein by reference, the inventors saw innovative use for a hollow module interior that creates a conduit channel for liquid cooling of high wattage devices (e.g. microprocessors, micro-controllers, high performance DDR memory chips, etc.) The Flex circuit based DIMM (or FlexDIMM) design incorporates a dual-cooling approach to solve the chips thermal management problem and allows heat to escape in two directions. The memory die and AMB chips or registered chips are enclosed and protected by thin metal plates that provide for electromagnetic, electrostatic and mechanical protection.

The FlexDIMM's thinner profile enables recovering precious board space at the OEM level. The built-in EMI shielding ensures modules can be placed closer together yet operate at higher frequency without incurring or causing electrical interference. Enhanced thermal cooling enables better utilization of existing air flow and control solutions while simultaneously improving module density.

However, one of the keys to successful cooling at the module level resides in ensuring that airflow is available at the right space between the modules, which is a subject of the current invention.

Air used for cooling always flows the path of least resistance; for this reason along with the pressure drop between adjacent modules, air may flow around the modules and not between them where it is needed the most for effective heat exhaust. The innovation resides in the fact that most previously proposed solutions are either module level solutions or blade server level solutions. The current innovative solution is hereby proposed that combines module and chassis level cooling for best optimal results. The innovative cooling solution hereby proposed.

Applicants have recognized a need for an integrated solution at the module level (or between modules) and the air flow circulation path at the blade server chassis level. The state of the art calls for thin modules (to leave ample space between adjacent modules) and no obstruction between modules (to minimize air impedance). It stands to reason that fundamentals behind these recommendations hold true. In the present invention however, the air path is engineered to force air though between modules regardless of minor obstructions because no other path is available that may offer lesser resistance to air passage. The minor obstruction introduced between adjacent modules in the current invention is a high performance heat exchanger.

The present invention is intended, among other things, to channel the air available for cooling inside the chassis of the computing device to force the air into selected channels in the memory bank (i.e., between the modules and not around the modules or some other path of least resistance).

This tunneled cooling (or collimated cooling) is made possible by using a set of baffles (or apertures) placed upstream of and between the cooling air supply and the memory bank area to force air to go only through the rectangular space available between adjacent modules in the memory bank of the high speed computing machines (super computers or blade servers in these cases). In some instances, it may be desirable to include both a blower fan, for forcing cool air through the baffles and through the heat exchanger(s) aligned with openings in the baffles, and a suction fan to draw or pull air as it exits the rear of the blade server chassis.

The current invention includes a high performance heat exchanger to be thermally coupled to the memory chips and either placed between adjacent modules (in the memory bank) or integrated within a cross sectional area of the module that is in the cooling air path; whereby, the heat from a given module is transferred laterally to a heat sink that, in turn, transfers the heat to the heat exchanger which in turn is placed in the path of cool air. However in this case, the cool air has no other alternative path but to pass through the high performance heat exchanger. The efficiency of heat exhaust is thereby maximized. Lateral heat conduction and removal is a preferred method for module cooling in order to minimize the total module height of vertically mounted Very Low Profile (VLP) memory modules.

The concept of designing a baffle around the memory bank to channel air between adjacent modules and to place a high performance heat exchanger between adjacent modules, is applicable to a wide range of modules; however, it is particularly suitable for a set of memory modules with unique packaging techniques that further enhance the heat exhaust.

Advanced computing systems require high-density memory modules. For this reason, the ability to build high-density memory modules that are fully reworkable and using minimal expensive “pre-stacked” memory chips is of considerable interest. The flex circuit used in the FlexDIMM allows for folds that effectively lead to a high packing density using existing standard chips. Furthermore, Applicants have provisions for replacing any defective chips after the assembly is complete. This is achieved though an innovation packaging technique described below.

Memory modules can be single rank (18 chips), dual rank (36 chips) or full (four) rank (72 chips). Higher density (a greater number of memory chips) enables higher overall computing capability. Pre-stacked memory die packages offer a way of increasing density at the memory module level. The pre-stacked die can be a dual die package (DDP) or a quad die package (QDP). Both the DDP and the QDP are more expensive that single or monolithic die. For this reason a reworkable module is called for to enable exchanging whatever defective package so that the module is made fully functional. It is obvious that module production yields are affected by the functionality of the various die.

### EXAMPLE 1.2 RANK FLEX DIMM

The single sided cooling Flex DIMM module consists of semiconductor components mounted to and interconnected by a multilayer flex circuit that is integrally (and thermally) coupled to the base side of a single sided heat sink. This configuration is mirrored about the center plane of the module completing the assembly. The removal of heat from the semiconductor devices is accomplished by conducting heat away from the component, through the flex circuit, and directly into the cooling air stream by the means of a single sided high performance forced convection heat sink. This heat sink utilizes a forced air convection heat transfer process to transport the heat from the heat sink base out to the dissipating surfaces and then into the cooling air stream. The forced convection cooling air stream impinges onto one end of the Flex DIMM module heat sink, and flows along the length of the heat sink dissipating surface. The high performance forced convection heat sink accomplishes its enhanced dissipating properties by the means of extended surfaces that protrude from the heat sink base into the cooling air stream offering a much larger surface area for transferring heat. These extended surfaces could take the form of longitudinal fins, perpendicular pins fins, or any type of array of features integral to heat sink base that protrude out from the base surface into the cooling air stream. The fins themselves could have any cross-sectional profiles such as rectangular, circular, diamond shaped, etc., and they could also be straight or tapered.

### EXAMPLE 2.4 RANK FLEX DIMM

The double sided cooling Flex DIMM module consists of semiconductor components mounted to and interconnected by a multilayer flex circuit that is integrally coupled to both sides of a double sided cold plate heat exchanger. This configuration is mirrored about the center plane of the module completing the assembly. The removal of heat from the semiconductor devices is accomplished by conducting heat away from the component, through the flex circuit, and directly into the cooling air stream by the means of a double sided, high performance, forced convection, cold plate heat exchanger. This heat exchanger utilizes a forced air convection heat transfer process to transport the heat from the heat exchanger sidewalls, to the dissipating surfaces, and into the cooling air stream. The forced convection cooling air stream impinges onto one end of the Flex DIMM module heat exchanger, and flows through the length of the enclosed heat exchanger sidewalls, across the heat exchanger sink dissipating surfaces. The high performance forced convection heat sink accomplishes its enhanced dissipating properties by the means of extended surfaces that protrude from one heat exchanger sidewall and to the other sidewall into the cooling sir stream offering a much larger surface area for transferring heat. These extended surfaces could take the form of thin plate fins of a variety of thickness and pitch. They could be of a straight or tapered cross-section and they could straight or wavy. The extended surfaces could also be pin fins that extend from one side wall to the other and they could have any cross-sectional profiles such as rectangular, circular, diamond shaped, etc., and they could also be straight or tapered. The shape and cross sectional area of the cooling fins is expected to be custom engineered for specific chassis enclosures and air flow specifications.

In a package memory die, heat escapes predominantly from the solder balls area than through the package itself. This holds true regardless of the package configuration single, dual or quad. For this reason, from a thermal management stand point, it is preferred to mount the chips on flex and attach the flex (with thermal vias) onto a heat sink that is in contact with cool air for best heat removal.

The innovative memory module configuration proposed in the current invention yields better thermal cooling, better thickness, lower height for VLP configurations, and built-in heat exchanger and offers full rework capability. For the best use, the chips are mounted on Flex and the flex opposite the solder balls of the chip is attached using a thermally conductive material to a heat sink that in turn is attached or integral with a heat exchanger. It may be better to attach the flex directly to a heat exchanger that act as the heat sink, mechanical protection and EMI shielding.

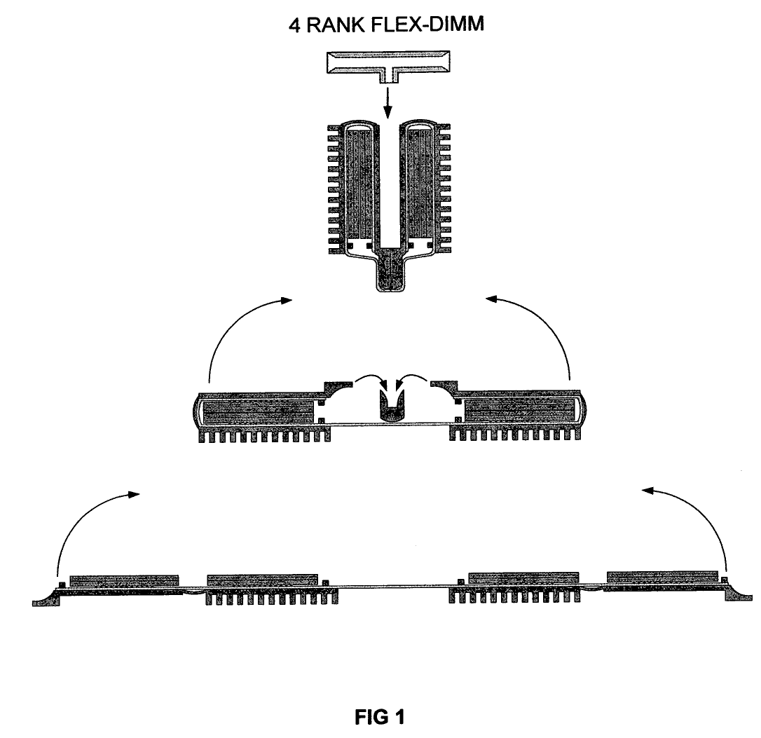

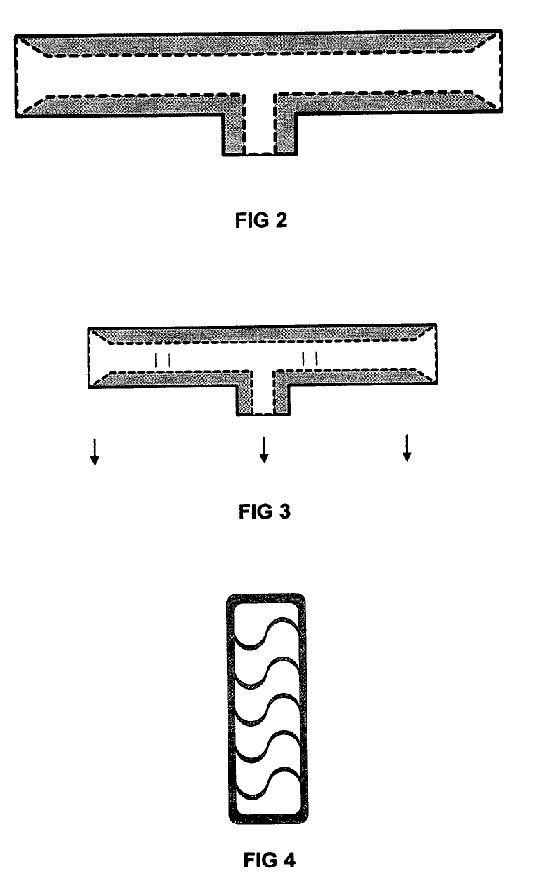

The innovative module packaging is shown for a full rank module (with DDP) in FIG. 1. Once the module is built, it can be opened for rework such as replacing any chips that are defective. Once the module is fully closed, additional cooling in the middle can be accomplished by a long lid shown schematically in FIGS. 2 and 3, having provisions for directing and forcing cooling air to cool the inner heat sink surfaces of the module.

This special lid can have a plurality of air inlets and outlets to direct the cooling air to the inside of the module but also the lateral heat sinks of the module.

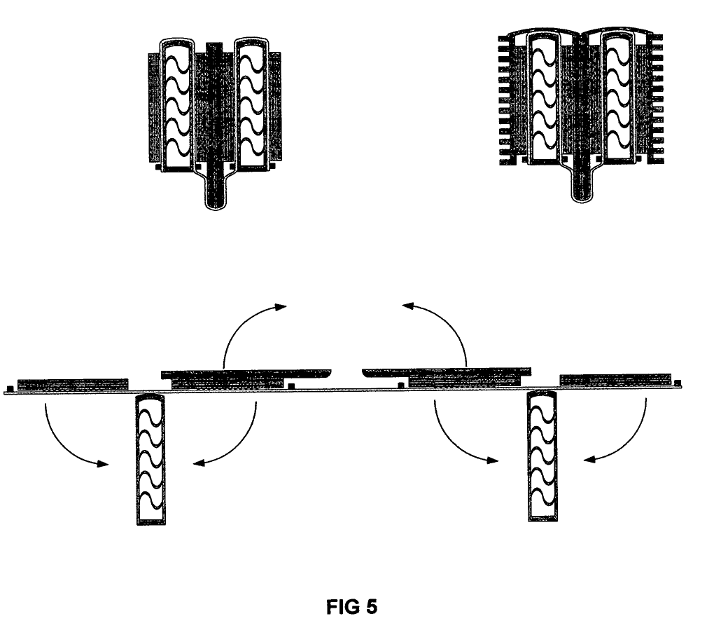

The configuration shown in FIG. 1 is just one example of a 4 rank flex DIMM. Other folding configurations are possible. Furthermore, the flat plate heat sink can be replaced by a high performance heat exchanger as shown in FIG. 4.

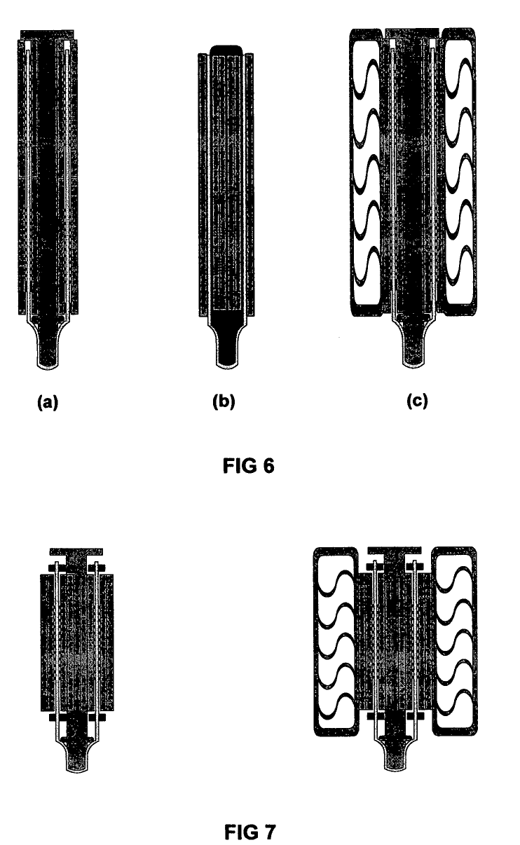

Using this high performance heat exchanger in combination with a different folding technique on the module would yield yet another 4 rank VLP DIMM with unprecedented thermal management capability. Also by adding heat sinks to further cool the chips on the die package side and to provide mechanical protection gives an ultimate module for heat exchange with full rework capability as shown schematically in FIG. 5.

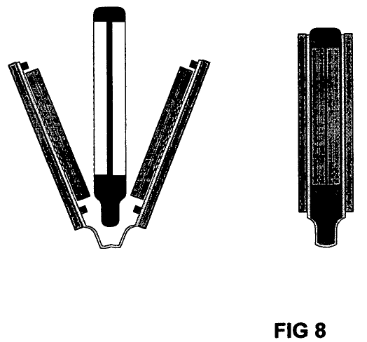

Another way of building a full rank module without folding the flex, to enable a VLP configuration, is possible as illustrated in FIG. 6. The chips can be mounted on a hollow (or indented metal frame) as in 6a or on the flex attached to external heat sinks that can be in contact with a high performance heat exchanger as in 6b. In turn the chips attached to a metal core can have external heat sinks that are of the high performance heat exchange kind as in 6c.

Yet another way of building a 4 rank VLP module with a low profile (i.e., short module height) is illustrated in FIG. 7 with and without the external heat sink heat exchangers

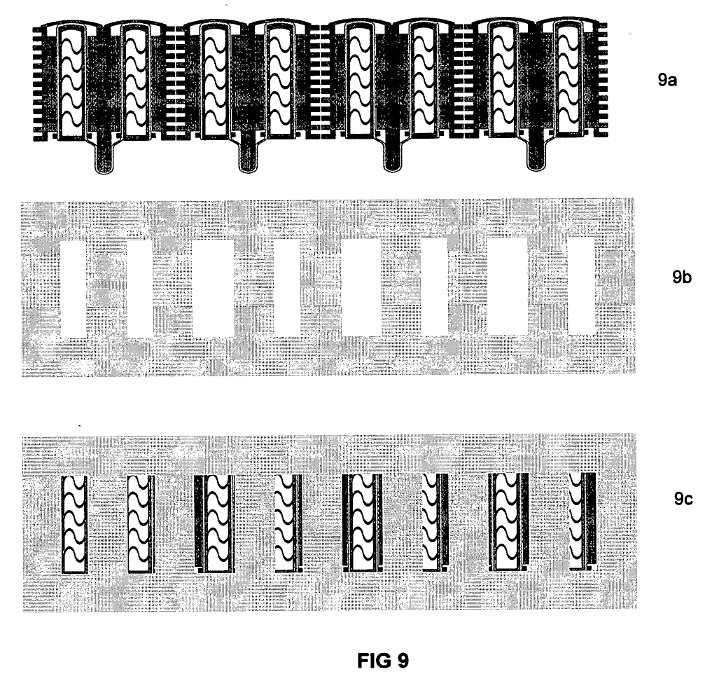

Instead of 4 rank modules, the same techniques can be used for dual rank modules as illustrated in FIG. 8.

To further illustrate the cooling technique in the current invention, a series of modules with build in heat exchangers are illustrated in FIG. 9 representing in a memory bank (9a). A multi-orifice aperture (or baffle) 9b that blocks the air from circulating below or above the memory bank is shown. Once the baffle is aligned with the memory bank (9c), the only air passage is the one defined by the high performance heat exchangers.

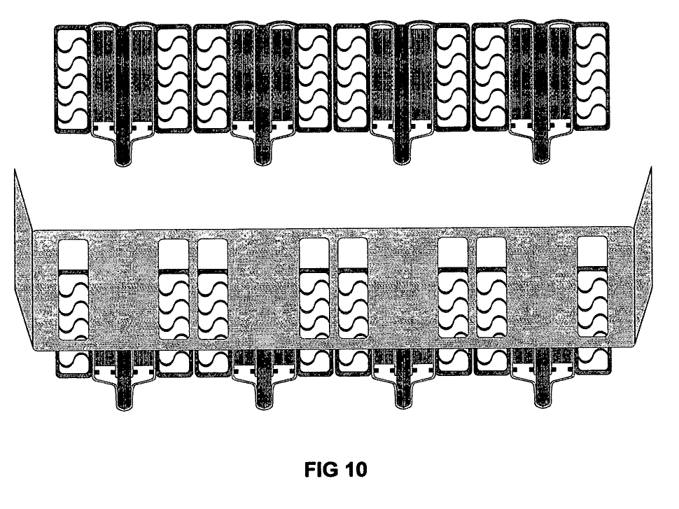

Similarly, the aperture can be tailored to a different module design as illustrated schematically in FIG. 10.

It will be appreciated that as an additional benefit, the tunneled cooling enables the modules to be placed closer together because air no longer propagates between modules by virtue of a path of least resistance. Air is now forced (by design) into high performance heat exchangers strategically placed in high-density modules to remove heat. Pressure drop between modules no longer dictates the airflow path. Rather, by engineering the air path to restrict and direct the airflow, designers using the present invention are able to bring the modules closer together and save precious board space or add more functionality.

The baffles illustrated above could be installed or fixed to the chassis as a separate shaped metal or plastic piece, or attached or integrated with the front cover of the Blade server chassis or press-fitted or clipped to some portion of the bank of DIMM sockets previously mounted within the server computer.

Although the descriptions within this provisional application are directed specifically to memory module devices and applications for server computer environments (e.g. Fully Buffered DIMM (FB-DIMM), Very Low Profile (VLP) DIMM, Registered (R-DIMM), Graphic (G-DIMM), etc.) it will be appreciated by those skilled in the art of electronic component packaging that other heat dissipating integrated cicruit (IC) devices, in particular microprocessor chips or graphic accelerator chips, can benefit from the invention, as will other end-use applications, such as high performance game computer consoles, workstations, and desktop or tower computers and even laptop or notebook computers.

It should also be noted that, although the cooling fluid discussed in some of the exemplary embodiments of the present invention is air, it will be understood that other gaseous or liquid cooling fluids, such as liquid fluorocarbons (e.g. Freon), water, helium, or other fluid known to one versed in the art of electronic component thermal cooling, may be employed in the present invention.

We claim:

1. A semiconductor multi-chip module comprising a flexible circuit wrapped around a hollow or finned heat exchanger.

2. The module of claim 1 further comprising substantially hollow heat exchangers on an external surface.

3. A semiconductor multi-chip module comprising a central air channel and a mating lid configured to provide for fluid cooling delivery to the center of the module.

4. A method of cooling a memory bank of semiconductor multi-chip modules using tunneled fluidic circulation through the use of multi-orifice apertures (baffles) placed at the front of the bank of modules and connected to the chassis of the electronic box to channel the air or fluid available for cooling inside the chassis of the computing device to force the air into selected channels in the memory bank.
